(19) United States
(12) Patent Application Publication
(10) Pub. No.: US 2025/0311437 A1
(43) Pub. Date: Oct. 2, 2025

(54) INTER-DIE CONNECTIVITY WITH A BACKEND SWITCH

(71) Applicant: Intel Corporation, Santa Clara, CA (US)

(72) Inventors: Abhishek A. Sharma, Portland, OR (US); Sagar Suthram, Portland, OR (US); Wilfred Gomes, Portland, OR (US); Tahir Ghani, Portland, OR (US); Anand S. Murthy, Portland, OR (US)

(73) Assignee: Intel Corporation, Santa Clara, CA (US)

(21) Appl. No.: 18/619,545

(22) Filed: Mar. 28, 2024

(51) Int. Cl. H01L 27/12; H01L 23/00; H01L 23/522; H01L 23/528

(52) U.S. Cl. CPC H10D 87/00; H01L 23/528; H01L 23/5226; H01L 24/08; H01L 2224/08145

(57) ABSTRACT

Integrated circuit (IC) structures including backend switches for inter-die connectivity are disclosed. In one example, an IC device includes a first device region and a second device region over a substrate (e.g., discrete device regions or dies), and a backend transistor (e.g., a backend transistor over one or more metal layers over the substrate), where the backend transistor is coupled with the first device region and the second device region. In one example, the first device region and the second device region may be coplanar device regions separated by a scribe region or stacked device regions. In one example, the pitch and/or thickness of a metal layer over the backend switch is smaller than the pitch and/or thickness of a layer below the backend switch.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C are cross-sectional side views of IC structures including multiple dies and a backend switch coupled with the dies, in accordance with various embodiments.

FIG. 2 illustrates a cross-sectional side view of backend of line (BEOL) layers of an IC device that includes a backend switch in accordance with examples described herein.

FIG. 3 is a block diagram of an example IC device that includes a plurality of dies and a plurality of backend switches, in accordance with any of the embodiments disclosed herein.

FIG. 4 is a block diagram of another example IC device that includes a plurality of dies interconnected with a plurality of backend switches, in accordance with any of the embodiments disclosed herein.

FIG. 5 is an example circuit diagram representing a backend switch for providing interconnection between two dies, in accordance with any of the embodiments disclosed herein.

FIG. 6 illustrates an example circuit diagram that includes transistors with interconnected gates, which may be implemented as backend switches in accordance with any of the embodiments disclosed herein.

FIG. 7 is a top view of a wafer and dies that may include any of the IC structures disclosed herein, in accordance with any of the embodiments disclosed herein.

FIG. 8 is a side, cross-sectional view of an IC package that may include any of the IC structures disclosed herein, in accordance with various embodiments.

FIG. 9 is a side, cross-sectional view of an IC device assembly that may include any of the IC structures disclosed herein, in accordance with any of the embodiments disclosed herein.

FIG. 10 is a block diagram of an example electrical device that may include any of the IC structures disclosed herein, in accordance with any of the embodiments disclosed herein.

### DETAILED DESCRIPTION

Disclosed herein are integrated circuit (IC) structures including backend switches for inter-die connectivity.

IC fabrication usually includes two stages. The first stage of IC fabrication is typically referred to as the front-end of line (FEOL). The second stage is referred to as the back-end of line (BEOL). In the FEOL, individual semiconductor devices components (e.g., transistor, capacitors, resistors, etc.) can be patterned in a wafer. In the BEOL, interconnect structures such as conductive lines and conductive vias, separated as needed by an insulator material, can be formed to provide connection between individual components. The BEOL usually starts with forming the first metal layer on the wafer. The first metal layer is often called M0. More metal layers can be formed on top of M0, and these metal layers are often called M1, M2, and so on.

In the FEOL, multiple device regions or dies are typically formed on a wafer, where each die has an area around its perimeter to enable subsequent singulation (also referred to as dicing), a process in which a wafer is cut into individual dies. Accordingly, adjacent dies on a wafer are separated by what is typically referred to as a scribe street, scribe line, or scribe region. The scribe regions typically lack devices (or at least lack devices that are coupled with devices of the dies) in FEOL layers, and thus may be considered “device free regions.” The scribe regions between adjacent dies also typically lack interconnects in the BEOL layers (or at least lack interconnects that are coupled with interconnects of the dies), and therefore may also be considered “metal free regions.” Accordingly, dies fabricated on a wafer typically lack interconnection and are electrically isolated from one another.

In accordance with examples described herein, IC structures can include backend switches to enable inter-die connectivity and communication. In one example, an IC structure or device includes coplanar dies that have not been singulated, where a backend transistor is coupled with the dies via interconnects that pass over the scribe region. In one such example, the interconnect layers between the dies and the switch may have metal lines with pitches that initially increase in relation to distance from the substrate the interconnect layer is (e.g., where a metal layer closer to the substrate and/or dies has a smaller pitch and a metal layer closer to the backend switch has a larger pitch), and an interconnect layer over the backend switch includes interconnects with a smaller pitch than the interconnect layer under the switch. In one example, the IC device may include two, three, four, or more dies that are interconnected with backend switches. In one such example, the IC device may include a wafer-level system with dies that are coupled via backend switches. In one example, an IC device may also, or alternatively, include multiple stacked dies that are communicatively coupled via a backend switch. In one example, a backend switch enables configurable connectivity and/or routing between dies.

IC structures with backend switches for inter-die connectivity as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with backend switches for inter-die connectivity as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

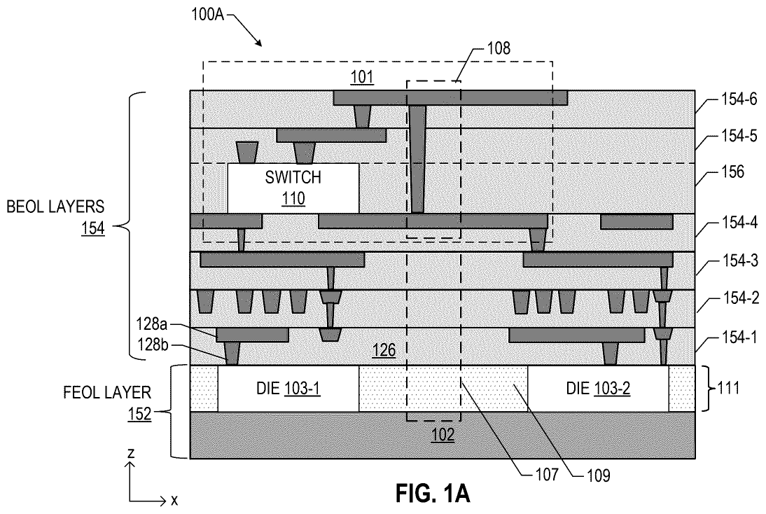

FIGS. 1A-1C are cross-sectional side views of IC structures including multiple dies and a backend switch coupled with the dies, in accordance with various embodiments.

Turning first to FIG. 1A, the IC device 100A includes a FEOL layer 152 and BEOL layers 154. The FEOL layer 152 includes a device region 111 over a substrate 102, where the device region 111 includes two dies 103-1, 103-2. The substrate 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups Ill and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The dies 103-1, 103-2 each include frontend devices (e.g., frontend transistors such as FinFETs, nanowire transistors, nanoribbon transistors, frontend memory cells, or other frontend devices). The dies 103-1 and 103-2 may be referred to as a first device region and a second device region, respectively, where the first device region and the second device region are discrete device regions (e.g., physically discrete device regions which may be surrounded by a scribe region). In the example illustrated in FIG. 1A, the dies 103-1 and 103-2 are substantially co-planar dies (i.e., located in a same plane that is substantially parallel to the substrate 102). The dies 103-1, 103-2 may be homogenous (e.g., substantially identical dies, such as two instances of the same type of die) or heterogenous (e.g., non-identical dies, such as two different types of dies with different arrangements of devices and interconnects). For example, in an IC device 100A in which the dies are homogenous, the dies 103-1, 103-2 may be two processor dies (e.g., two substantially same instances of the same processor die, such as two dies with substantially the same arrangement of devices and interconnects). In an example IC device 100A in which the dies 103-1, 103-2 are heterogenous, the die 103-1 may be a processor/compute die and the die 103-2 may be a memory die, an accelerator die (e.g., a graphics processing unit or other graphics accelerator, an artificial intelligence (AI) accelerator, etc.), or other type of die. In one example in which the IC device 100A includes at least two different types of dies, the IC device 100A may be a system on a chip (SoC). Although only two dies are shown in FIG. 1A, IC structures with multiple dies interconnected with backend switches may include more than two dies (e.g., three, four, eight, etc.).

The dies 103-1 and 103-2 are adjacent to one another (e.g., there is not an intervening die between the dies 103-1, 103-2), and are separated from one another by a scribe region 107. The scribe region 107 (which may also be referred to as a scribe street or scribe line), is a region between adjacent dies 103-1, 103-2 that lacks devices in the layer(s) of the device region 111. Typically, the scribe region 107 is void of devices in a plane where frontend devices would typically be present (i.e., a plane substantially parallel to the substrate) to provide a region in which the wafer may be cleaved, scribed, milled, ablated, scored, or otherwise processed during a singulation process to separate adjacent dies from one another. In another example, one or more devices may be present in a scribe region, but the devices in the scribe region lack connectivity with devices in the device region 111 of the adjacent dies 103-1, 103-2. The IC device 100A may include one or more materials 109 in the scribe area between the dies 103-1, 103-2. For example, the materials 109 may include one or more of an insulator material, a semiconductor material, and/or a conductive material. In one example, the dimensions of the scribe region may vary depending on implementation, and may be defined by the dimensions of the dies 103-1, 103-2 and the distance between the dies 103-1, 103-2. For example, the scribe region 107 may include an area or region between the adjacent edges or perimeters of the first die 103-1 and the second die 103-2 between a first plane and a second plane, where the first and second planes are substantially orthogonal to the substrate 102 and substantially parallel with the adjacent edges or perimeters of the dies 103-1, 103-2 (e.g., the first and second planes are substantially parallel with the y-z plane as shown in FIG. 1A, where the y-axis is going into and coming out of the page). Thus, a scribe region may include a region or regions (e.g., along the x-axis and along the y-axis) that defines the perimeters of a die or dies, which may be device-free, or may include devices that lack interconnectivity outside of the scribe region.

The BEOL layers 154 may include a plurality of backend interconnects electrically coupled to (e.g., in electrically conductive contact with at least portions of) one or more of the plurality of FEOL devices of the FEOL layer 152. Various BEOL interconnect layers 154 may be/include one or more metal layers of a metallization stack of the IC device. Various metal layers of the BEOL interconnect layers 154 may be used to interconnect the various inputs and outputs of the devices (e.g., logic devices) in the FEOL layer 152. In one example, each of the BEOL interconnect layers 154 may include vias and lines/trenches. For example, the BEOL interconnect layer 154-1 includes a via portion 128b and a line or trench/interconnect portion 128a. The trench portion 128a of a metal layer is configured for transferring signals and power along electrically conductive (e.g., metal) lines (also sometimes referred to as “trenches”) extending in the x-y plane (e.g., in the x or y directions), while the via portion 128b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 154 may include only certain patterns of conductive metals, e.g., copper (Cu), aluminum (Al), tungsten (W), or cobalt (Co), or metal alloys, or more generally, patterns of an electrically conductive material, formed in an insulating medium such as an ILD 126. The insulating medium may include any suitable ILD materials such as silicon oxide, carbon-doped silicon oxide, silicon carbide, silicon nitride, aluminum oxide, and/or silicon oxynitride. In some embodiments, the dielectric material 126 disposed between the interconnect structures in different ones of the interconnect layers may have different compositions; in other embodiments, the composition of the dielectric material 126 between different interconnect layers may be the same. The example illustrated in FIG. 1A depicts six interconnect layers 154-1-154-6, however, fewer or more interconnect layers may be present. Generally, the scribe region 107 is void of conductive interconnects to facilitate dicing of the dies. However, as discussed in more detail below, in the example in FIG. 1A, there are conductive interconnects present in one or more of the higher up metal layers.

In the example illustrated in FIG. 1A, the IC device 100A includes a switch 110 over one or more of the interconnect layers (e.g., over the interconnect layers 154-1-154-4 as shown in FIG. 1A). A switch 110 that is over an interconnect layer may be considered a “backend switch” due to its location in a BEOL layer. In one example, the switch 110 is disposed over a metal 6 (M6) layer or beyond (e.g., M7, M8, M9, M10, etc., where MX represents the Xth metal layer over the frontend device region 111). In one such example, there are at least six metal layers between the dies 103-1, 103-2 and the switch 110. In other examples, the switch 110 may be in a lower metal layer (e.g., in a metal layer before M6). Thus, in the illustrated example, the switch 110 is depicted as being disposed in a backend device layer 156, which is between two interconnect layers 154-4 and 154-5. In one example, the switch 110 is a transistor (e.g., a “backend transistor”). For example, In one example, the switch 110 may include a transistor of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field.

The switch 110 is coupled with both the first die 103-1 and the second die 103-2 via conductive interconnects. To facilitate interconnectivity between the switch 110 and the dies 103-1, 103-2, one or more conductive interconnects may pass over the scribe region 107 between the adjacent dies 103-1, 103-2. In the illustrated example, although the lower interconnect layers below the switch 110 lack metal lines across the scribe region 107, one or more higher interconnect layers include one or more metal lines in the scribe region (where interconnect layers are “lower” in the metallization stack if the layers are closer to the substrate 102, and “higher” in the metallization stack if the layers are further from the substrate 102). For example, the interconnect layers 154-1-154-4 include a metal-free portion in the scribe region 107, as is depicted in FIG. 1A, and the interconnect layers 154-4, 154-5, and 154-6 include one or more conductive interconnects over the scribe region (e.g., in the region 108 indicated by the dashed contour).

In the example illustrated in FIG. 1B, the switch 110 is coupled to an interconnect over the scribe area 107 (e.g., in order to couple the first die 103-1 to the second die 103-2). Thus, unlike conventional IC devices, the IC device 100A includes multiple un-singulated dies (e.g., a first die 103-1 and a second die 103-2) over the substrate 102 with a continuous device-free region (e.g., the scribe region 107) between the first die 103-1 and the second die 103-2, and an interconnect layer with a metal line over the continuous device-free region. In one such example, metal lines are absent from the lower interconnect layers and present in one or more upper interconnect layers in a plane intersecting the scribe region 107, where the plane is substantially orthogonal to the substrate and substantially parallel to an edge of the dies 103-1, 103-2. For example, as shown in FIG. 1A, metal lines are present in an interconnect layer 154-4 directly below the switch 110 and in the layers 154-5, 154-6 over the switch 110, and absent from the interconnect layers 154-1, 154-2, and 154-3 in the scribe region 107. Although not shown in FIG. 1A, devices may also be present over the scribe region 107 (e.g., in or over the upper metal layers).

Thus, the IC structure includes dies 103-1, 103-2 as fabricated over the substrate 102 and separated by a region 107 without having been diced, where the dies 103-1, 103-2 are coupled with one another via the switch 110 and one or more conductive interconnects that pass over the scribe region 107. The switch 110 may include, for example, a backend transistor that is coupled with both the first die 103-1 and the second die 103-2 to enable communication between the dies 103-1, 103-2. In one example, the switch 110 and interconnects coupling the switch 110 with the dies 103-1, 103-2 may form a backend “network switch” 101 in the sense that signals may be routed between un-singulated dies over a substrate.

FIG. 1B is a cross-sectional side view of another IC device 100B that includes multiple dies and a backend switch coupled with the dies, in accordance with various embodiments. The IC device 100B of FIG. 1B differs from the IC device 100A of FIG. 1A in that the IC device 100B includes a stacked configuration. A stacked device with devices both below and over interconnect layers may fabricated with a variety of techniques, including techniques to bond multiple IC structures together, layer transfer techniques, techniques to epitaxially grow a semiconductor material in the backend, and/or other techniques that enable fabricating an IC device with devices over or in a BEOL layer. As illustrated in FIG. 1B, the IC device 100B includes a first IC structure 101-1 and a second IC structure 101-2 that is stacked over the first IC structure 101-1. In the example illustrated in FIG. 1B, the second IC structure 101-2 is bonded to the first IC structure 101-1, and therefore IC device 100B includes a bonding interface 113 between the IC structures 101-1, 101-2.

Each of the IC structures 101-1, 101-2 includes a FEOL layer including one or more dies and BEOL layers, and at least one of the IC structures 101-1, 101-2 includes one or more backend switches. For example, in FIG. 1B, the IC structure 101-1 includes a FEOL layer 152-1 with a device region 111-1 including dies 103-1, 103-2 and BEOL layers 154-1. Similarly, the IC structure 101-2 includes a FEOL layer 152-2 with a device region 111-2 including dies 103-3, 103-4. The dies 103-1, 103-2, 103-3, and 103-3 may be homogenous or heterogeneous, or a combination (e.g., some of the dies 103-1, 103-2, 103-3, and 103-3 may be homogenous while others are different). In one example that includes at least two types of dies, the IC device 100B may be or include a stacked SoC. In the example illustrated in FIG. 1B, the IC structures are bonded back-to-back (i.e., one of the BEOL layers 154-1 of the IC structure 101-1 is bonded with one of the BEOL layers 154-2 of the IC structure 101-2). However, in other examples, the IC structures 101-1, 101-2 may be bonded together with different orientations than the example depicted in FIG. 1B (e.g., back-to-face or face-to-face). Also, although FIG. 1B illustrates an example of an IC device 100B with two IC structures 101-1, 101-2 bonded together, in other examples, more than two IC structures may be bonded together (e.g., three IC structures, four IC structures, etc.).

The IC device 100B includes multiple switches 110-1-110-N (of which switches 110-1 and 110-N are labeled). In one example in which IC structures are bonded together, at least one of the IC structures includes the switches 110-1-110-N, but in other examples, one or more switches may be present in each of the IC structures of the IC device. For example, FIG. 1B depicts the IC device 100B in which the switches 110-1-110-N are in the first IC structure 101-1, but not the second IC structure 101-2. In another example, one or more switches (e.g., the switch 110-1) may be a part the first IC structure 101-1, and one or more other switches (e.g., the switch 110-N) may be a part of the second IC structure 101-2. The number of switches 110-1-110-N present in the IC device 100B may depend on the number of dies and interconnections amongst the dies. For example, an IC device that includes two dies may include one switch to enable interconnection between the two dies, an IC device that includes three dies may include, for example, three switches to provide interconnectivity amongst all three dies with every other die or fewer than three switches to provide interconnectivity between some of the dies, and so forth.

Like FIG. 1A, FIG. 1B illustrates an example IC device 100B in which one or more conductive interconnects pass over a scribe region 107-1. In the example illustrated in FIG. 1B, both IC structures 101-1, 101-2 have corresponding scribe regions 107-1, 107-2, and conductive interconnects are present in a region 108 between the two scribe regions 107-1, 107-2. Although not illustrated in FIG. 1B, devices may also be present over or in the scribe region in one or more BEOL layers. For example, one or more of the switches 110-1-110-N may be in the region 108 over the scribe region 107-1. Depending on implementation, a switch may connect two coplanar dies or two stacked dies. For example, the switch 110-1 may be coupled with two coplanar dies, such as the dies 103-1, 103-2, or the dies 103-3, 103-4. In another example, the switch 110-1 may be coupled with two stacked dies, such as the dies 103, 103-3 or the dies 103-1, 103-4. In an example where a switch couples two coplanar dies, there may be conductive interconnects over a scribe region between the coplanar dies. In an example where a switch couples two stacked dies, there may or may not be interconnects over a scribe region, depending on the location of the stacked dies relative to scribe regions. FIG. 1C is a cross-sectional side view of another IC device 100C that includes multiple dies and a backend switch coupled with the dies, in accordance with various embodiments. The IC device 100C of FIG. 1C includes a stacked configuration like the IC device 100B of FIG. B; however, the IC device 100C differs from the IC device 100B of FIG. 1B in that the IC device 100C does not include conductive interconnects over the scribe region. In the example illustrated in FIG. 1C, the IC device 100C includes a first IC structure 121-1 and a second IC structure 121-2, where the IC structures 121-1, 121-2 include dies 103-1, 103-2, respectively. The IC device 100C includes a switch 110 to vertically couple the die 103-1 with the die 103-2, which is stacked over the die 103-1.

Thus, FIGS. 1A-1C illustrate example IC devices 100A-100C that includes multiple dies and one or more backend switches to provide interconnections between dies. As mentioned briefly above, a backend switch is a switch in and/or over a BEOL layer. In some examples, the backend switch may be over multiple metal layers, such as over M6 or a higher metal layer. The thickness of metal layers and the pitch of the conductive interconnects in those metal layers may be larger in layers that are higher up (e.g., further from a substrate over which the metal layers are disposed).

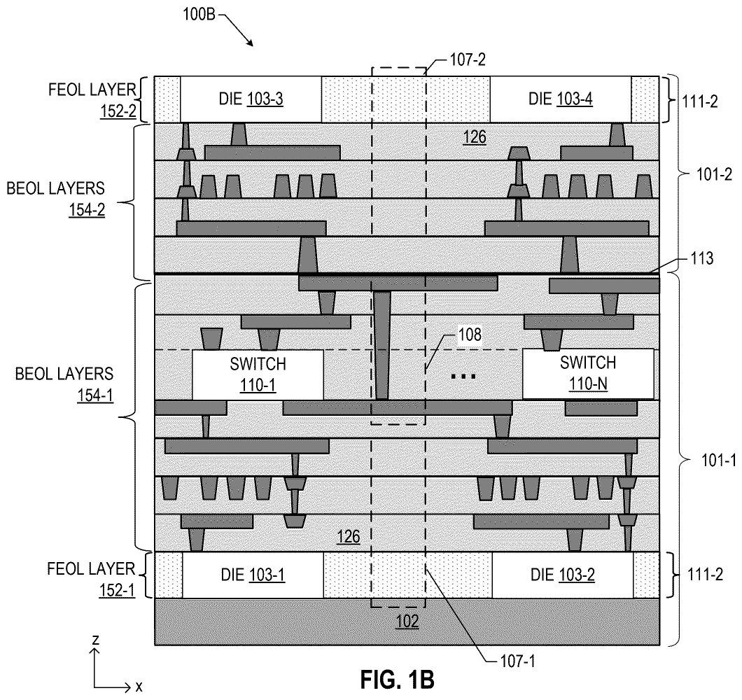

FIG. 2 illustrates a cross-sectional side view of BEOL layers of an IC device 200 that includes a backend switch in accordance with examples described herein. In the example illustrated in FIG. 2, the IC device 200 includes a metallization stack 201 with a first plurality of interconnect layers 204-1 (which may also be referred to as metal layers), which includes X metal layers M0-MX. The IC device 200 includes a BEOL layer 202 with a backend switch 110 over the first plurality of interconnect layers 204-1, and a second plurality of interconnect layers 204-2 (of which interconnect layers MX+1 and MX+2 are depicted). The ellipses (three dots) indicate that IC device 200 may include more interconnect layers in the first plurality of interconnect layers 204-1 and/or in the second plurality of interconnect layers 204-2 than is depicted in FIG. 2. In one example, the metallization stack may further include global metal layers (e.g., layers GM0, GM1, etc.) over the local metal layers M0-MX, MX+1, MX+2, etc. In one such example, global metal layers have a larger thickness and pitch relative to lower metal layers, and may include, for example, a hybrid bonding layer, a pad layer, etc., in addition to, or instead of, metal lines and vias. The interconnect layers 204-1, 204-1 are depicted in FIG. 2 as having metal lines running in one direction (e.g., layers M0, M2, and MX+1 are shown as having metal lines extending along the x-axis, and layers M1, MX, and MX+2 are shown as having metal lines extending along the y-axis, where the y-axis is going into and coming out of the page). However, an interconnect layer may include conductive interconnects along more than one axis. Also, FIG. 2 does not specifically depict conductive vias, however, any or all of the layers M0-MX, MX+1, MX+2, and/or the BEOL device layer 202 may include conductive vias extending along the z-axis.

In one example, the metallization stack 201 is over one or more dies (such as the dies 103-1, 103-2 of FIG. 1A) over a substrate. The IC device 200 includes a scribe region 107, which may lack metal lines in metal layers that are closer to the substrate (e.g., in the metal layers M0-MX), and may include metal lines in metal layers over the switch 110 (e.g., in the layers MX+1 and MX+2). One or more conductive interconnects that extend over the scribe region 107 may enable coupling the switch 110 with dies on either side of the scribe region 107. As mentioned above, the dimensions of the scribe region 107 may vary depending on implementation. Scribe regions between different pairs of adjacent dies and/or around different dies may have the same or different widths, and different portions of a scribe region around a die may have the same or different widths. In one example, the width W_{scribe} may be in a range of 10 microns to 500 microns. Other scribe region widths are also possible.

In the example illustrated in FIG. 2, increasingly higher up interconnect layers of the first plurality of interconnect layers 204-1 have greater thicknesses relative to the previous layers. For example, in FIG. 2, the layer M0 represents the interconnect layer that is the closest to a substrate over which the interconnect layer was formed, and the layer MX+2 is shown as the interconnect layer that is furthest from the substrate. Note that in a stacked implementation, an IC device may include multiple substrates; in one such example, the proximity of an interconnect layer relative to a substrate refers to the interconnect layer's proximity to the substrate over which that interconnect layer was formed/provided, and which is a part of the same monolithic IC structure (e.g., not a substrate that is separated from the interconnect layer by a bonding interface). For example, the IC device 200 may include a first substrate below the layer M0, and a second substrate that is a part of a second IC structure over the layer MX+2. In one such example, the layer M0 is still considered to be closer to the substrate than the layer MX+2 due to M0's proximity to the substrate over which the metallization stack 201 was formed.

Referring again to the relative thicknesses of the layers M0-MX, in one example, the layer M0 has a thickness TO and the layer M1 has a thickness T1, where T1 is greater than TO, the layer M2 has a thickness T2 that is greater than T1, and the layer MX has a thickness TX that is greater than T2. Similarly, conductive interconnects in increasingly higher up interconnect layers of the first plurality of interconnect layers 204-1 have wider pitches relative to conductive interconnects in the previous layers. For example, conductive interconnects in the layer M1 have a pitch P1 and conductive interconnects in the layer MX have a pitch PX, where PX is greater than P1. Thus, the thickness of subsequent metal layers M0-MX and the pitch of interconnects in those metal layers increase the further away from the substrate the metal layer is. In some examples, one or more metal layers may have similar or substantially the same thicknesses and/or pitches (e.g., metal lines in M0 and M2 may have a similar pitch). However, the higher up metal layers (e.g., above M5, above M6, above M7, etc.) generally include interconnects having a larger pitch than interconnects in the lower metal layers (e.g., M0, M1, M2, etc.).

According to one example, the switch 110 may be disposed over a relatively high up metal layer. For example, where X represents number of a metal layer, X may be in a range of 5-12, e.g., the switch 110 may be over the metal layer over M5, M6, M7, M8, M9, M10, M11, M12, etc. In one such example, the switch is between metal layers M5 and M10, between metal layers M5-M7, or between metal layers M6 and M7. In another example, the switch may be located between or above a global metal layer. In an example in which the backend switch is located in a global metal layer, the backed switch 110 may be utilized for power switching (e.g., to change the voltage level provided to a die). In one such example, the pitch PX of metal lines in a layer below (e.g., directly below or under) the switch 110 may be in a range of about 100-700 nanometers, or 100-500 nanometers, or 100-400 nanometers, where a metal layer is directly under or below the switch if there are no other intervening metal layers between the switch 110 and the metal layer that is directly under the switch. For example, the metal lines in a metal layer that is directly under the switch may include vias between the metal lines and the switch, but there are not other intervening metal lines between the switch and the metal lines in the metal layer that is directly under the switch. Similarly, a metal layer is directly over the switch if there are no other intervening metal layers between the switch 110 and the metal layer that is directly over the switch. In one example, the thickness of a metal layer may include the thickness of the metal line plus the height of vias in the metal layer. In one example, the thickness of the metal layer may depend on the pitch of metal lines in the metal layer. In one such example, the aspect ratio of metal line thickness to metal line pitch may be about 2.5:1 or less.

As mentioned above, the metal layer thicknesses and the metal line pitches of metal layers below the switch 110 typically flare out such that each subsequent metal layer is thicker and has metal lines with a larger pitch. In contrast to the metal layers below the switch 110, one or more interconnect layers over the backend switch 110 (e.g., directly over) have a smaller thickness and interconnect pitch relative to one or more lower metal layers below (e.g., directly below) the backend switch 110. In one example, the metal layer directly below the switch 110 has metal lines with a pitch that is about 2-20 times larger, 3-15 about times larger, or about 4-7 times larger than the pitch of metal lines in a metal layer over the switch 110. For example, the metal layer MX+1 over the backend switch 110 may have a thickness TX+1, and the metal layer MX+2 over the backend switch 110 may have a thickness TX+2, where one or both of TX+1 and TX+2 are smaller than the thickness TX of a metal layer directly under the switch 110. Similarly, the metal layer MX+1 may include interconnects having a pitch PX+1 (not shown in FIG. 2) and the metal layer MX+2 may include interconnects having a pitch PX+2, one or both of which are smaller than the pitch PX. In one example, the pitch PX+1 and/or PX+2 are in a range of 200 nm to 1 micron. Thus, in the example illustrated in FIG. 2, the IC device 200 includes a metallization stack 201 over one or more dies that with metal pitches that become wider in higher up layers below the switch 110, and then become narrower in one or more layers over the switch 110. For example, the metallization stack 201 includes a first plurality of interconnect layers 204-1 and a backend switch 110 over the first plurality of interconnect layers 204-1, where the first plurality of interconnect layers 204-1 includes a first interconnect layer (e.g., MX) with first metal lines having a first pitch (e.g., TX). The metallization stack 201 includes a second plurality of interconnect layers 204-2 over the backend switch 110, where the second plurality of interconnect layers 204-2 includes a second interconnect layer (e.g., MX+2) with second metal lines having a second pitch (e.g., PX+2), and wherein the first pitch is larger than the second pitch. Note that although the pitch is not shown for the layer MX+1, the layer MX+1 may have conductive interconnects with a pitch that is smaller than the pitch PX of a layer under the switch 110.

Thus, the IC device 200 includes multiple dies over a substrate, where the multiple dies include at least a first die and a second die, a plurality of interconnect layers over at least one of the multiple dies, where the plurality of interconnect layers have conductive interconnects with pitches that initially increase with distance from the substrate, and then decrease with distance from the substrate (e.g., for one or more interconnect layers over the switch 110). For example, the IC device 200 includes a first interconnect layer (e.g., M1 as shown in FIG. 2) including first metal lines having a first pitch (e.g., P1), a second interconnect layer (e.g., MX) over the first interconnect layer, wherein the second interconnect layer includes second metal lines having a second pitch (e.g., PX) that is greater than the first pitch, and a third interconnect layer (e.g., MX+2) over the second interconnect layer, where the third interconnect layer includes third metal lines having a third pitch (e.g., PX+2) that is smaller than the second pitch. In one example, the IC device 200 includes a switch 110 between the second interconnect layer and the third interconnect layer, where the switch includes a backend transistor electrically coupled with the first die and the second die.

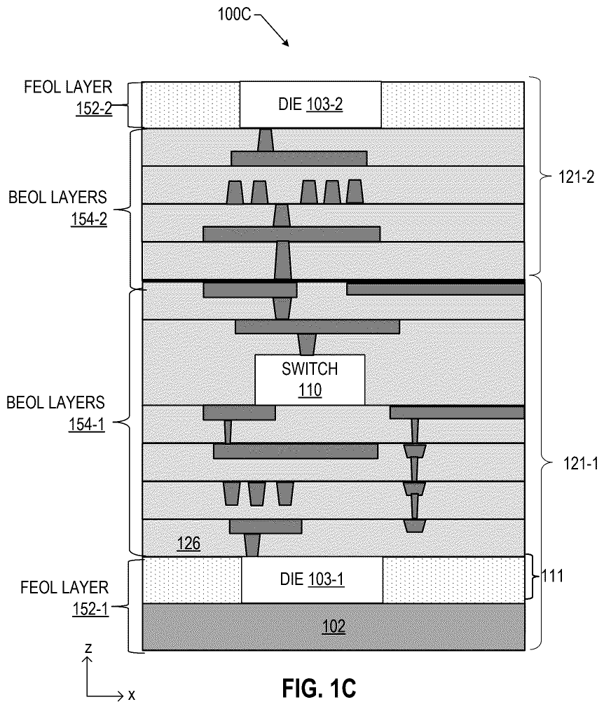

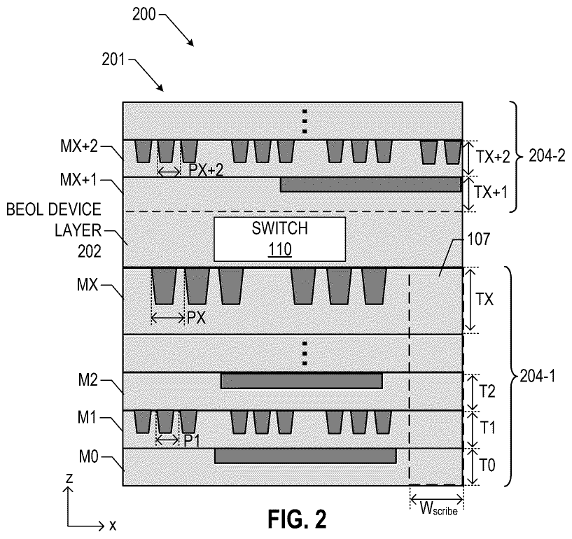

As mentioned above, an IC device may include one or multiple backend switches to provide interconnectivity amongst multiple dies. The number of interconnected dies may vary depending on the implementation, and may include two dies and a single backend switch, or more than two dies and more than two backend switches. FIGS. 3 and 4 are block diagrams illustrating IC devices with a plurality of dies and backend switches. FIG. 3 is a block diagram of an IC device 300 that includes M dies 303-1-303-M (of which dies 303-1, 303-2, and 303-M are shown), and N backend switches 310-1-310-N (of which backend switches 310-1, 310-2, and 310-N are shown). The dies 303-1-303-M may be coplanar, stacked, or a combination of coplanar and stacked dies. The dies 303-1-303-M may include homogenous dies, heterogenous dies, or a combination of homogenous and heterogenous dies. As mentioned above, various implementations may include various numbers of dies and backend switches. In one example, there may be one switch coupling a pair of dies, or a plurality of switches coupling a pair of dies (e.g., an IC device may include different switches to route different signals between two dies).

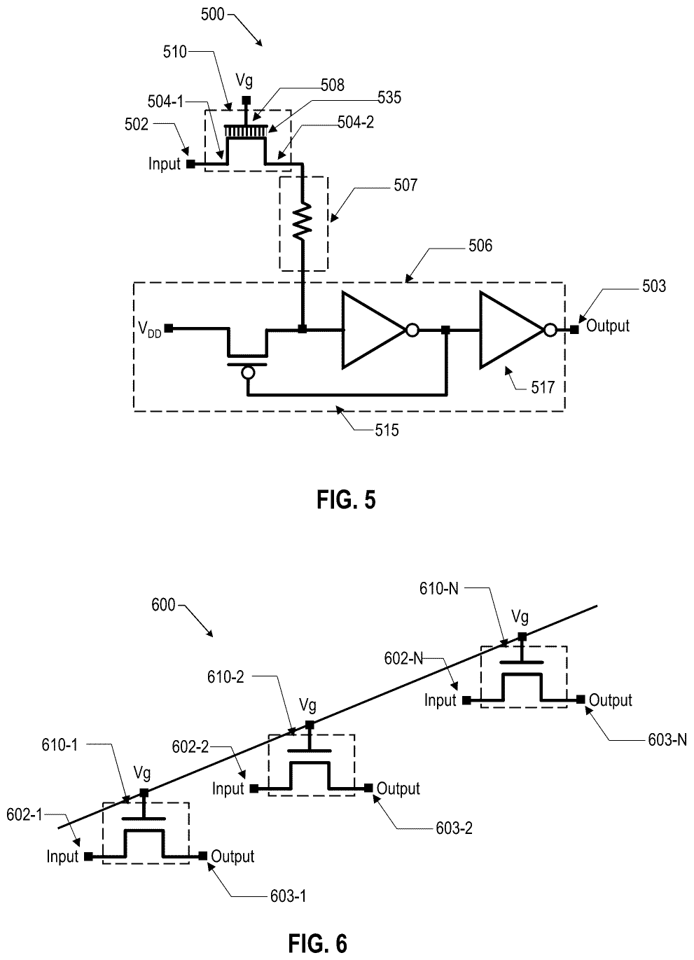

FIG. 4 is a block diagram of an IC device 400 that includes a plurality of dies interconnected with a plurality of backend switches. The IC device 400 includes four dies 403-1, 403-2, 403-3, and 403-4. In the example illustrated in FIG. 4, the dies 403-1, 403-2, 403-3, and 403-4 are fully interconnected such that each of the dies 403-1, 403-2, 403-3, and 403-4 is coupled with every other one of the dies 403-1, 403-2, 403-3, and 403-4 via a backend switch. For example, the die 403-1 is coupled with the die 403-2 via the switch 410-12, the die 403-1 is coupled with the die 403-3 via the switch 410-13, and the die 403-1 is coupled with the die 403-4 via the switch 410-14. the die 403-2 is coupled with the die 403-3 via the switch 410-23 and the die 403-2 is coupled with the die 403-4 via the switch 410-24. Although the example in FIG. 4 illustrates fully interconnected dies 403-1, 403-2, 403-3, and 403-4, in other examples, some dies may not be connected to one another with a backend switch (for example, the die 403-1 may be coupled with one more of the dies 403-2, 403-3, and 403-4, and the dies 403-2, 403-3, 403-4 may only be connected with the die 403-1). Although FIG. 4 illustrates an example IC device 400 with four dies and six switches, in other examples, an IC device may include fewer than four dies or more than four dies (e.g., two dies, three dies, eight dies, etc.), and/or fewer than six switches or more than six switches (e.g., one switch, two switches, ten switches, etc.). In one example, although FIG. 4 shows a single switch between dies (e.g., a single switch 410-12 between the dies 403-1, 403-2), an IC device may include multiple switches between dies (e.g., to route multiple signal lines between two dies). Although not shown in FIG. 4, one or more of the switches 410-12, 410-13, 410-24, 410-32, 410-14, 410-34 may be coupled with one another. An example of interconnected backend switches is discussed below with respect to FIG. 6.

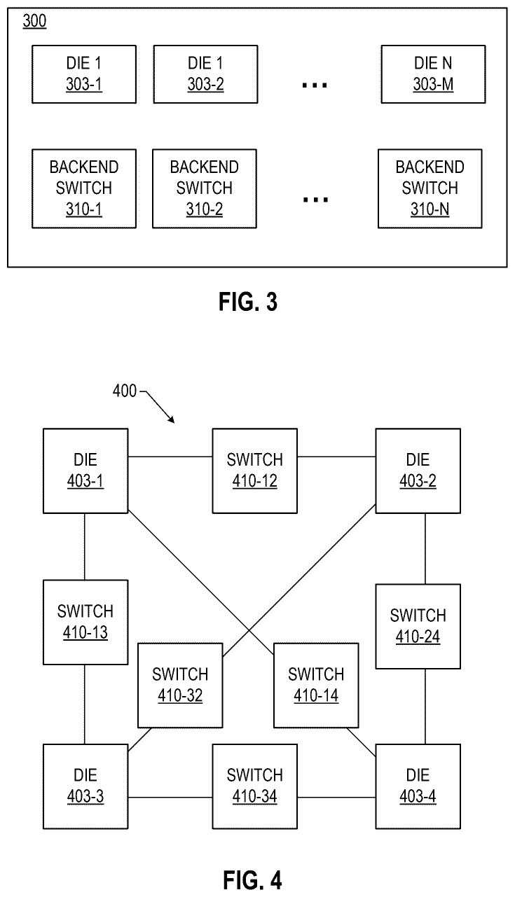

FIG. 5 is an example circuit diagram representing a backend switch for providing interconnection between two dies. The circuit diagram 500 includes a backend transistor 510, which may function as a switch, coupled with circuitry 506 that may include, for example, a level restorer circuit 515, an output driver 517, and or other circuitry. The transistor may be an example of the switch 110 discussed above with respect to FIGS. 1A-1C, FIG. 2, and FIGS. 3-4. The transistor 510 has a gate terminal 508 and two source or drain terminals 504-1, 504-2. In the example illustrated in FIG. 5, a first source or drain terminal 504-1 is coupled with a first die via the node 502 (labeled “input” in FIG. 5) and a second source or drain terminal 504-2 is coupled with a second die via the node 503 (labeled “output” in FIG. 5). In the example illustrated in FIG. 5, the second die is coupled with the transistor 510 via intervening circuitry 506 and a conductive interconnect 507 (e.g., shown with a resistor in FIG. 5). According to various examples, depending on the location of the dies coupled with the transistor 510, the conductive interconnects between the transistor and the dies may be conductive vias and/or conductive lines or traces. In an example in which the transistor 510 is coupled with dies in separate layers (e.g., stacked dies), the interconnect 507 may include a conductive via. In one such example where the IC device includes stacked dies that are bonded together, the different dies may be considered different tiers, and the conductive interconnect 507 may include an inter-tier via (e.g., a via that connects two tiers and which may extend between the two tiers). In some examples, the interconnect 507 may represent multiple conductive lines and one or more vias. In one such example, the interconnect 507 may pass over a scribe region, such as the conductive interconnects in the region 108, discussed above with respect to FIG. 1A.

The transistor 510 may be a backend transistor of any suitable architecture, such as a planar transistor, a FinFETs, a nanowire/nanoribbon transistor, a thin film transistor (TFT), a hysteretic transistor such as a ferroelectric FET (FeFET), or any other suitable transistor. In one example, implementing the backend switch as a hysteretic transistor may enable the switch to be in an on or off state until programmed otherwise. For example, the transistor 510 may be different from conventional logic transistors in that, instead of or in addition to a gate dielectric material that may be included in the gate, the transistor 510 may further includes a hysteretic material or a hysteretic arrangement, which, together, may be referred to as a “hysteretic element 535” (schematically illustrated in FIG. 5 as short parallel vertical lines integrated with the notation of the gate of the transistor 510). In this manner, the hysteretic element 535 is integrated into the gate of the transistor 510 and the transistor 510 may be described as a “hysteretic transistor.” The hysteretic element 535 integrated in the gate of the transistor 510, and may have a thickness that may, in some embodiments, be between about 0.5 nanometers and 10 nanometers, including all values and ranges therein (e.g., between about 1 and 8 nanometers, or between about 0.5 and 5 nanometers).

In some embodiments, the hysteretic element 535 may be provided as a layer of a ferroelectric (FE) or an antiferroelectric (AFE) material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic elements of the transistor 510 are within the scope of the present disclosure.

In other embodiments, the hysteretic element 535 may be provided as a stack of alternating layers of materials that can trap charges. In some such embodiments, the stack may be a two-layer stack, where one layer is a charge-trapping layer, and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. In some embodiments of the hysteretic element 535 being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.” In one example, the transistor may be “programmed” by setting the polarization of the hysteretic element 535. In other examples, the transistor 510 may be a non-hysteretic transistor (e.g., a transistor without a hysteretic or charge-trapping element). In one example, a network switch coupling two dies is the transistor 510. In some examples, a network switch coupling two dies includes the transistor 510 and one or more additional components, such as one or more capacitors coupled with the transistor 510.

In one example, an IC device includes a plurality of backend switches, where the backend switches are interconnected. For example, FIG. 6 illustrates an example of a circuit diagram 600 with N transistors 610-1-610-N (of which transistors 610-1, 610-2, and 610-N are shown) with interconnected gates. In the example illustrated in FIG. 6, each of the transistors 610-1-610-N may be coupled with two dies. For example, the transistor 610-1 has one source or drain terminal coupled with one die via the input node 602-1, and another source or drain terminal coupled with another die via the output node 603-1. The transistor 610-2 has one source or drain terminal coupled with one die (which may be one of the same dies coupled with the transistor 610-1 or a different die) via the input node 602-2, and another source or drain terminal coupled with another die (which may be one of the same dies coupled with the transistor 610-1 or a different die) via the output node 603-2. The transistor 610-N has one source or drain terminal coupled with one die (which may be one of the same dies coupled with the transistors 610-1 and/or 610-2 or a different die) via the input node 602-N, and another source or drain terminal coupled with another die (which may be one of the same dies coupled with the transistors 610-1 and/or 610-2 or a different die) via the output node 603-N.

Depending on the implementation, backend switches coupling dies on an IC device may be independently controlled, or connected together and controlled together. For example, in some implementations the gates of all the backend transistors functioning as switches 110 on an IC device may be interconnected. In one such example, the interconnected transistors may be referred to as a fully interconnected network switch. In the example illustrated in FIG. 6, the gates of the transistors 610-1-610-N are coupled together with one or more conductive interconnects, such as metal lines and/or vias, as discussed above. In one such example, the transistors 610-1-610-N may thus be controlled (e.g., turned on or off) together. In other examples, an IC device may include one or more subsets of backend switches that are interconnected (e.g., two or more first switches may be interconnected e.g., via the gates of transistors of the first switches may be connected to one another), and one or more second switches may not be connected with the first switches (e.g., the gates of transistors of the second switches may not be connected with the gates of the first switches). In other examples, an IC device may include multiple switches that are independently controlled (e.g., the gates of the independent backend switches are not coupled together).

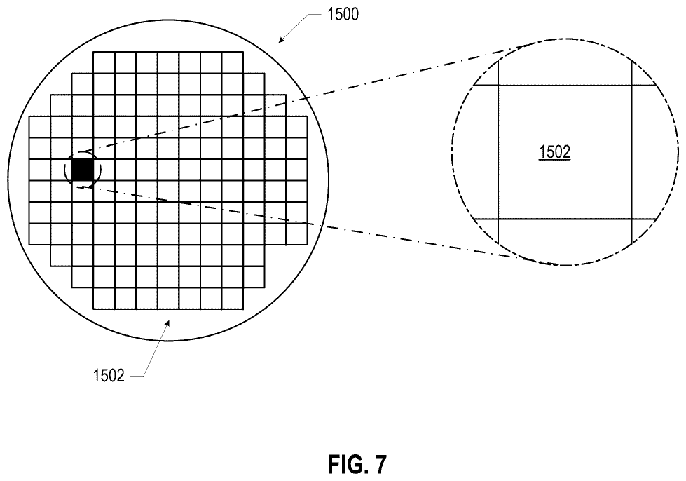

Thus, a backend switch in accordance with examples described can enable bridging two dies to provide communication between the two dies. In one such example where the two dies are substantially coplanar un-singulated dies over a substrate, the backend switch may be coupled with one or more conductive interconnects that pass over a scribe region between the dies. In some examples, an IC device may also, or alternatively, include a backend switch that couples two stacked dies. IC structures with backend switches for inter-die routing in accordance with techniques described herein may be included in any suitable electronic component or electronic device. FIGS. 7-10 illustrate various examples of apparatuses that may include one or more of the IC structures with backend switches for inter-die connectivity disclosed herein.

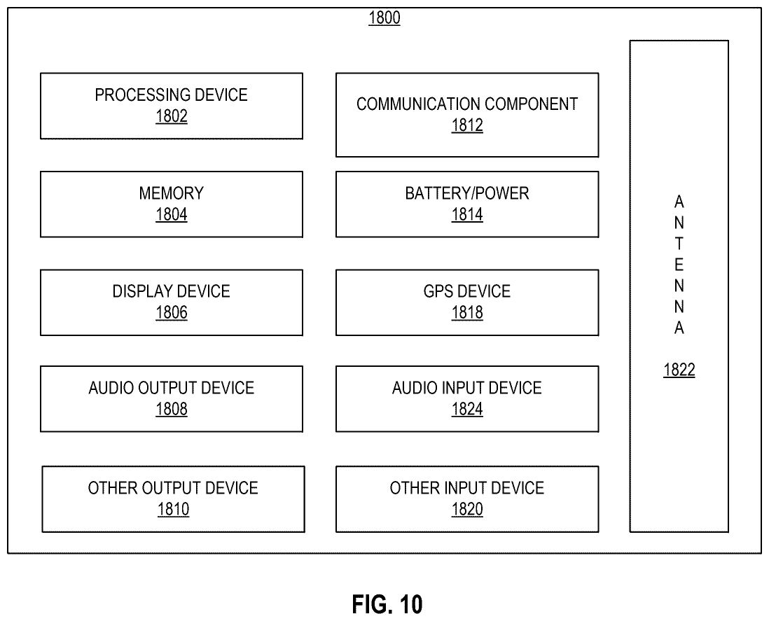

FIG. 7 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. In one example, the dies 1502 may include two or more different dies (e.g., heterogenous dies as discussed above, with different arrangements of devices and interconnects). After the fabrication of the semiconductor product is complete, the wafer 1500 may undergo a singulation process in which the dies 1502 are separated from one another to provide discrete “chips” of the semiconductor product. As mentioned above, in some examples, the wafer 1500 does not undergo a singulation process, and the dies 1502 on the wafer 1500 are interconnected with backend switches to form a wafer-level system. In other examples, a singulation process involves separating some, but not all dies from one another. In one such example, a singulation process may involve separating subsets or groups of dies from one another, where the subsets or groups of dies may include two or more dies that are interconnected with backend switches, as described herein. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

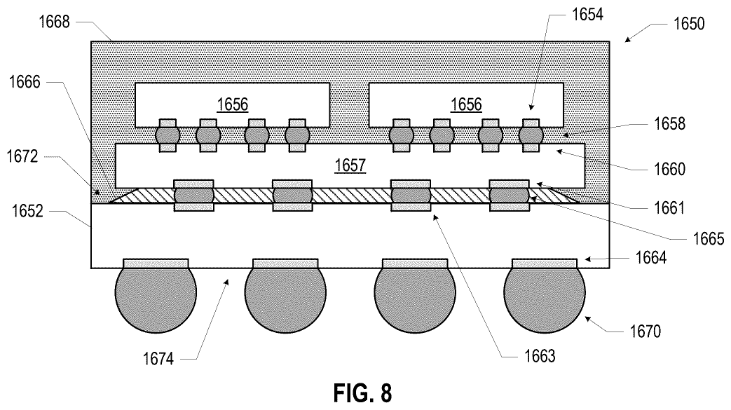

FIG. 8 is a side, cross-sectional view of an example IC package 1650 that may include one or more IC structures with backend switches for inter-die connectivity in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 8 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 8 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

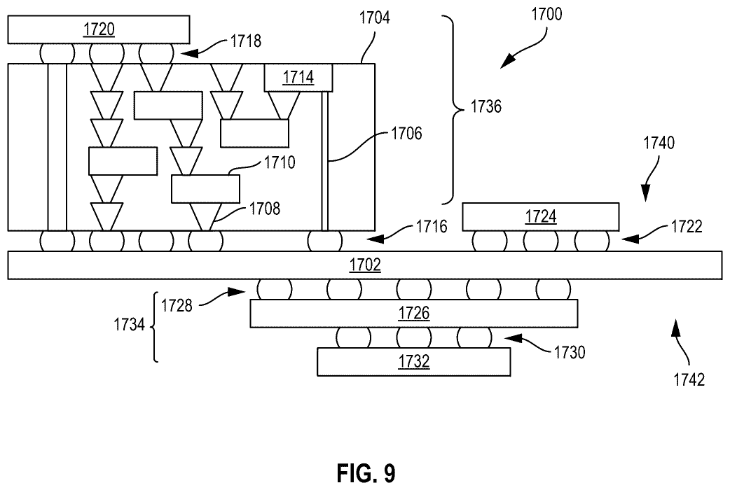

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 8 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 9.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 8 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 8, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 9 is a side, cross-sectional view of an IC device assembly 1700 that may include one or more IC packages or other electronic components (e.g., a die) including one or more IC structures with backend switches for inter-die connectivity in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 8 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 7), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 9, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example electrical device 1800 that may include one or more IC structures with backend switches for inter-die connectivity in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 10 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 10, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an integrated circuit (IC) device, including a first device region (e.g., a first die) and a second device region (e.g., a second die) over a substrate; a metallization stack over the first device region, where the metallization stack includes a first plurality of interconnect layers; and a transistor over the first plurality of interconnect layers, where the backend transistor is coupled with the first device region and the second device region, and where: the first plurality of interconnect layers includes a first interconnect layer with first metal lines having a first pitch, the metallization stack further includes a second plurality of interconnect layers over the backend transistor, where the second plurality of interconnect layers includes a second interconnect layer with second metal lines having a second pitch, and the first pitch is larger than the second pitch.

Example 2 provides the IC device of example 1, further including a region (e.g., a scribe region) between the first device region and the second device region, where: the first interconnect layer lacks metal lines in the region, the second interconnect layer includes a metal line in the region, and the backend transistor includes a source or drain region that is coupled with the metal line.

Example 3 provides the IC device of example 2, where: the first device region and the second device region include frontend transistors in a first layer over the substrate; and the region lacks devices in the first layer.

Example 4 provides the IC device of any one of examples 1-3, where: the first plurality of interconnect layers includes five or more metal layers.

Example 5 provides the IC device of any one of examples 1-3, where: the first device region and the second device region are in a same plane over the substrate.

Example 6 provides the IC device of any one of examples 1-3, where: the second device region is over the second plurality of interconnect layers.

Example 7 provides the IC device of any one of examples 1-6, where the backend transistor is a first backend transistor, and where the IC device further includes a third device region over the substrate; and a second backend transistor over the first plurality of interconnect layers, where the second backend transistor is coupled with the third device region a further device region, where the further device region is one of the first device region, the second device region, or a fourth device region.

Example 8 provides the IC device of example 7, where: the first backend transistor has a first gate terminal; the second backend transistor has a second gate terminal; and the first gate terminal and the second gate terminal are coupled with a common conductive interconnect. 8b. The IC device of any one of claims 1-8, where: the backend transistor is a hysteretic transistor.

Example 9 provides an integrated circuit (IC) device, including a first device region over a substrate; a second device region over the substrate, where the second device region is substantially coplanar with the first device region; a scribe region between the first device region and the second device region; a first interconnect layer over the first device region and the second device region; a second interconnect layer over the first interconnect layer, where the second interconnect layer includes a metal interconnect in the scribe region; and a transistor over the first interconnect layer and coupled with the metal interconnect of the second interconnect layer, where: the transistor includes a first terminal electrically coupled with the first device region and a second terminal electrically coupled with the second device region, and one of the first terminal and the second terminal is a source terminal of the transistor and another one of the first terminal and the second terminal is a drain terminal of the transistor.

Example 10 provides the IC device of example 9, where: the transistor is between the first interconnect layer and the second interconnect layer.

Example 11 provides the IC device of any one of example 9-10, where: the first interconnect layer includes a first plurality of conductive interconnects with a first pitch; the second interconnect layer includes a second plurality of conductive interconnects with a second pitch; and the second pitch is smaller than the first pitch.

Example 12 provides the IC device of example 11, further including a third interconnect layer over the second interconnect layer, where: the third interconnect has a third pitch, and where the third pitch is larger than the second pitch.

Example 13 provides the IC device of any one of examples 9-12, where: the transistor is a hysteretic transistor.

Example 14 provides the IC device of any one of examples 9-13, further including a plurality of interconnect layers over the first device region and the second device region, where the plurality of interconnect layers includes the first interconnect layer and the second interconnect layer, and where the transistor is over a sixth interconnect layer of the plurality of interconnect layers.

Example 15 provides the IC device of any one of examples 9-14, where the transistor is a first transistor, and where the IC device further includes a third device region; and a second transistor over the first interconnect layer, where the second transistor is electrically coupled with the third device region, and one of the first device region and the second device region.

Example 16 provides the IC device of example 15, where: the third device region is co-planar with the first device region.

Example 17 provides the IC device of example 15, further including a third interconnect layer over the first transistor, where the third die is in a layer over the third interconnect layer.

Example 18 provides the IC device of any one of examples 9-17, where: a cross-section of the IC device lacks devices in the scribe region in a layer in which devices are present in the first device region, or the cross-section lacks devices that are coupled with the first device region or the second device region in the layer, where the cross-section is along a plane that is substantially orthogonal to the substrate and that intersects the first device region and the second device region.

Example 19 provides a system, including multiple device regions over a substrate, the multiple device regions including a first device region and a second device region; a plurality of interconnect layers over at least one of the multiple device regions, where the plurality of interconnect layers include: a first interconnect layer including first metal lines having a first pitch, a second interconnect layer over the first interconnect layer, where the second interconnect layer includes second metal lines having a second pitch that is greater than the first pitch, and a third interconnect layer over the second interconnect layer, where the third interconnect layer includes third metal lines having a third pitch that is smaller than the second pitch; and a switch between the second interconnect layer and the third interconnect layer, where the switch includes a backend transistor electrically coupled with the first device region and the second device region.

Example 20 provides the system of example 19, where: the multiple device regions are heterogenous device regions stacked over one another over the substrate.

Example 21 provides the system of example 20, further including a bonding interface between two interconnect layers that are between the switch and one of the multiple device regions.

Example 22 provides the system of example 19, where: the first device region and the second device region are in a plane that is substantially parallel with the substrate; and the first device region is separated from the second device region by a region in the plane.

Example 23 provides the system of example 22, where: the plane is a first plane; and metal lines are absent from the second interconnect layer and present in the third interconnect layer in a second plane intersecting the region, where the second plane is substantially orthogonal to the substrate and substantially parallel to an edge of the first device region.

Example 24 provides the system of any one of examples 19-23, where: the plurality of device regions includes two or more of: a processor die, a memory die, a graphics processor die, and an accelerator die.

Example 25 provides the IC device according to any one of examples 1-18 or the system according to any one of examples 19-24, where the IC device or system includes or is a part of a central processing unit.

Example 26 provides the IC device or system according to any one of examples 1-25, where the IC device or system includes or is a part of a memory device.

Example 27 provides the IC device or system according to any one of examples 1-26, where the IC device or system includes or is a part of a logic circuit.

Example 28 provides the IC device or system according to any one of examples 1-27, where the IC device or system includes or is a part of input/output circuitry.

Example 29 provides the IC device or system according to any one of examples 1-28, where the IC device or system includes or is a part of a field programmable gate array transceiver.

Example 30 provides the IC device or system according to any one of examples 1-29, where the IC device or system includes or is a part of a field programmable gate array logic.

Example 31 provides the IC device or system according to any one of examples 1-30, where the IC device or system includes or is a part of a power delivery circuitry.

Example 31 provides an IC package that includes an IC device according to any one of examples 1-30; and a further IC component, coupled to the IC device.

Example 31 provides the IC package according to example 31, where the further IC component includes a package substrate.

Example 32 provides the IC package according to example 31, where the further IC component includes an interposer.

Example 33 provides the IC package according to example 31, where the further IC component includes a further IC device/die.

Example 34 provides a computing device that includes a carrier substrate and an IC device coupled to the carrier substrate, where the IC device is an IC device according to any one of examples 1-30, or the IC device is included in the IC package according to any one of examples 31-33.

Example 35 provides the computing device according to example 34, where the computing device is a wearable or handheld computing device.

Example 36 provides the computing device according to examples 34 or 35, where the computing device further includes one or more communication chips.

Example 37 provides the computing device according to any one of examples 34-36, where the computing device further includes an antenna.

Example 38 provides the computing device according to any one of examples 34-37, where the carrier substrate is a motherboard.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first device region and a second device region over a substrate;
a metallization stack over the first device region, wherein the metallization stack includes a first plurality of interconnect layers; and
a backend transistor over the first plurality of interconnect layers, wherein the backend transistor is coupled with the first device region and the second device region, and wherein:
the first plurality of interconnect layers includes a first interconnect layer with first metal lines having a first pitch,
the metallization stack further includes a second plurality of interconnect layers over the backend transistor, wherein the second plurality of interconnect layers includes a second interconnect layer with second metal lines having a second pitch, and
the first pitch is larger than the second pitch.

2. The IC device of claim 1, further comprising:
a region between the first device region and the second device region, wherein:
the first interconnect layer lacks metal lines in the region,
the second interconnect layer includes a metal line in the region, and
the backend transistor includes a source or drain region that is coupled with the metal line.

3. The IC device of claim 2, wherein:
the first device region and the second device region include frontend transistors in a first layer over the substrate; and
the region lacks devices in the first layer.

4. The IC device of claim 1, wherein:
the first plurality of interconnect layers includes five or more metal layers.

5. The IC device of claim 1, wherein:
the first device region and the second device region are in a same plane over the substrate.

6. The IC device of claim 1 wherein:
the second device region is over the second plurality of interconnect layers.

7. The IC device of claim 1, wherein the backend transistor is a first backend transistor, and wherein the IC device further comprises:
a third device region over the substrate; and
a second backend transistor over the first plurality of interconnect layers, wherein the second backend transistor is coupled with the third device region a further device region, wherein the further device region is one of the first device region, the second device region, or a fourth device region.

8. The IC device of claim 7, wherein:
the first backend transistor has a first gate terminal;
the second backend transistor has a second gate terminal; and
the first gate terminal and the second gate terminal are coupled with a common conductive interconnect.

9. An integrated circuit (IC) device, comprising:
a first device region over a substrate;
a second device region over the substrate, wherein the second device region is substantially coplanar with the first device region;
a scribe region between the first device region and the second device region;
a first interconnect layer over the first device region and the second device region;
a second interconnect layer over the first interconnect layer, wherein the second interconnect layer includes a metal interconnect in the scribe region; and
a transistor over the first interconnect layer and coupled with the metal interconnect of the second interconnect layer, wherein:
the transistor includes a first terminal electrically coupled with the first device region and a second terminal electrically coupled with the second device region, and
one of the first terminal and the second terminal is a source terminal of the transistor and another one of the first terminal and the second terminal is a drain terminal of the transistor.

10. The IC device of claim 9, wherein:
the transistor is between the first interconnect layer and the second interconnect layer.

11. The IC device of claim 9, wherein:
the first interconnect layer includes a first plurality of conductive interconnects with a first pitch;
the second interconnect layer includes a second plurality of conductive interconnects with a second pitch; and
the second pitch is smaller than the first pitch.

12. The IC device of claim 11, further comprising:
a third interconnect layer over the second interconnect layer, wherein:
the third interconnect has a third pitch, and wherein the third pitch is larger than the second pitch.

13. The IC device of claim 9, wherein:
the transistor is a hysteretic transistor.

14. The IC device of claim 9, further comprising:
a plurality of interconnect layers over the first device region and the second device region, wherein the plurality of interconnect layers includes the first interconnect layer and the second interconnect layer, and wherein the transistor is over a sixth interconnect layer of the plurality of interconnect layers.

15. The IC device of claim 9, wherein the transistor is a first transistor, and wherein the IC device further comprises:
a third device region; and
a second transistor over the first interconnect layer, wherein the second transistor is electrically coupled with the third device region, and one of the first device region and the second device region.

16. The IC device of claim 15, wherein:
the third device region is co-planar with the first device region.

17. The IC device of claim 15, further comprising:
a third interconnect layer over the first transistor, wherein the third device region is in a layer over the third interconnect layer.

18. The IC device of claim 9, wherein:
a cross-section of the IC device lacks devices in the scribe region in a layer in which devices are present in the first device region, or the cross-section lacks devices that are coupled with the first device region or the second device region in the layer, wherein the cross-section is along a plane that is substantially orthogonal to the substrate and that intersects the first device region and the second device region.

19. A system, comprising:
multiple device regions over a substrate, the multiple device regions including a first device region and a second device region;
a plurality of interconnect layers over at least one of the multiple device regions, wherein the plurality of interconnect layers include:
a first interconnect layer including first metal lines having a first pitch,
a second interconnect layer over the first interconnect layer, wherein the second interconnect layer includes second metal lines having a second pitch that is greater than the first pitch, and
a third interconnect layer over the second interconnect layer, wherein the third interconnect layer includes third metal lines having a third pitch that is smaller than the second pitch; and
a switch between the second interconnect layer and the third interconnect layer, wherein the switch includes a backend transistor electrically coupled with the first device region and the second device region.

20. The system of claim 19, wherein:
the multiple device regions are heterogenous device regions stacked over one another over the substrate.
